(19) United States
(12) Patent Application Publication
(10) Pub. No.: US 2023/0178430 A1
(43) Pub. Date: Jun. 8, 2023

(54) ELECTROPLATING COBALT, NICKEL, AND ALLOYS THEREOF

(71) Applicant: Lam Research Corporation, Fremont, CA (US)

(72) Inventors: Natalia V. Doubina, Tigard, OR (US); Tighe A. Spurlin, Portland, OR (US); Edward C. Opocensky, Aloha, OR (US); Jonathan David Reid, Sherwood, OR (US)

(21) Appl. No.: 17/998,067

(22) PCT Filed: Apr. 27, 2021
(86) PCT No.: PCT/US2021/029467

§ 371 Date: Nov. 7, 2022

Related U.S. Application Data
(60) Provisional application No. 62/704,407, filed on May 8, 2020.
(60) Provisional application No. 62/706,765, filed on Sep. 9, 2020.

(51) Int. Cl. H01L 21/768; C25D 7/12; C25D 3/12; C25D 3/56; C25D 5/02; C25D 5/50; C25D 17/00; C25D 21/12; C25D 21/08

(52) U.S. Cl. CPC H01L 21/76879; H01L 21/76898; C25D 7/123; C25D 3/12; C25D 3/562; C25D 5/02; C25D 5/50; C25D 17/001; C25D 21/12; C25D 21/08; H01L 21/76873

(57) ABSTRACT

Disclosed are apparatus, systems, and methods for electroplating cobalt, nickel, and alloys thereof in interconnect features of partially or fully fabricated electronic devices. During electroplating, cobalt, nickel, or alloys thereof fill features by a bottom up electrofill mechanism. Examples of features that may be electrofilled with cobalt, nickel, or alloys thereof include micro TSVs, contacts for devices, and certain gates for transistors. Electroplating apparatus may include electroplating cells along with one or more instances of each of a post-electrofill module, an anneal chamber, a plasma pretreatment module, and a substrate pre-wetting module.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in its entirety and for all purposes.

### BACKGROUND

Tungsten is sometimes used to form interconnects for various integrated circuit structures such as through silicon vias (TSVs) and device contacts. Tungsten interconnects are often deposited by chemical vapor deposition or atomic layer deposition.

Background and contextual descriptions contained herein are provided solely for the purpose of generally presenting the context of the disclosure. Much of this disclosure presents work of the inventors, and simply because such work is described in the background section or presented as context elsewhere herein does not mean that it is admitted to be prior art.

### SUMMARY

Certain aspects of this disclosure pertain to methods of forming an interconnect in an electronic device. Such methods may be characterized by the following operations: (a) contacting a substrate comprising a partially or fully fabricated integrated circuit with an aqueous electroplating solution having a pH of about 2 to about 5 and nickel and/or cobalt ions, and (b) controlling an electrical current and/or voltage to the substrate, thereby electroplating nickel and/or cobalt from the electroplating solution, via a bottom up fill mechanism, into the features. In certain embodiments, the aqueous electroplating solution comprises (i) nickel ions in a concentration of about 20 to about 80 g/L and/or cobalt ions in a concentration of about 10 to about 40 g/L, and (ii) a suppressor. In certain embodiments, the substrate comprises features having a diameter of about 0.005-6 micrometers and a feature depth of about 0.05-10 micrometers.

In certain embodiments, the substrate features are micro TSV features. In some applications, the operation of electroplating nickel and/or cobalt into the one or more features produces one or more interconnects between first electronic devices on a first side of the substrate to second electronic devices on a second side of the substrate. In some cases, the features have a depth of about 1000 nm to about 2000 nm and an opening diameter or width of about 50 nm to about 150 nm.

In certain embodiments, electroplating nickel and/or cobalt into the one or more features produces one or more electrical contacts directly to a first electronic device on the substrate. In some cases, the one or more electrical contacts contact one or more 3D NAND devices. In some implementations, the features have a depth of about 50 nm to about 500 nm and an opening diameter or width of about 5 nm to about 20 nm.

In some embodiments, the aqueous electroplating solution comprises no accelerator or leveler. In alternative embodiments, the aqueous electroplating solution comprises an accelerator and/or a leveler. In some embodiments, the aqueous electroplating solution comprises an accelerator. In certain embodiments, the aqueous electroplating solution further comprises boric acid.

In some embodiments, the aqueous electroplating solution additionally includes ions of a metal other than cobalt or nickel. In such embodiments, the operation of controlling the electrical current and/or voltage to the substrate electroplates a nickel alloy or a cobalt alloy from the electroplating solution into the features. In some such embodiments, the metal other than cobalt or nickel may be Cu, Ag, Au, Mn, Fe, Cr, Ru, Mo, Ir, Re, Pd, W, Mo, Pt, or any combination thereof. In some such embodiments, the metal other than cobalt or nickel is W or Mo. In some cases, the aqueous electroplating solution further comprises ions of Mo and/or ions of W in a concentration of about 0.1 to about 30 g/L. In certain embodiments, the aqueous electroplating solution includes a complexing agent that complexes nickel ions, cobalt ions, or the ions of a metal other than cobalt or nickel.

In some embodiments, the operation of controlling an electrical current and/or voltage to the substrate comprises increasing the electrical current while electroplating nickel and/or cobalt from the electroplating solution. In some cases, increasing the current comprises ramping the electrical current.

In some implementations, prior to electroplating nickel and/or cobalt, the method includes an operation of pretreating the substrate with a plasma to reduce metal oxide on a conductive layer in the one or more features. In some cases, prior to electroplating nickel and/or cobalt, the method includes prewetting the substrate, under reduced pressure, with a wetting solution that wets the features. In some cases, after electroplating nickel and/or cobalt, the method includes annealing the substrate.

Certain aspects of this disclosure pertain to apparatus for processing a substrate, which apparatus may be characterized by the following features: (a) a one or more electroplating cells; (b) one or more post electrofill modules; (c) a plasma pretreatment module; (d) a pre-wetting module; (e) one or more substrate transfer handlers; and (f) a controller configured to cause the one or more substrate transfer handlers to process first substrates by transferring them to each of the modules in (b), (c), and (d), and to process second substrates without transferring them to at least one of modules (b), (c), and (d) during the entire period when the second substrates are within the apparatus.

In some embodiments, the apparatus includes a frame or chassis enclosing the one or more electroplating cells, the one or more post electrofill modules, the prewetting module, and the plasma pretreatment module. In some embodiments, the frame or chassis additionally encloses the substrate transfer robot. In some cases, the pre-wetting module and the plasma pretreatment module are in a common vacuum environment.

In some embodiments, the apparatus also includes an anneal chamber configured to heat the substrate after electroplating in the one or more electroplating cells. In some embodiments, the apparatus also includes a load lock. In some cases, the prewetting module and the pretreatment module are connected by the load lock.

In certain embodiments, the controller is further configured to cause the apparatus to: (i) process a first substrate by transferring it to the plasma pretreatment module and transferring it to the pre-wetting module prior to transferring it to a first one of the one or more electroplating cells; and (ii) process a second substrate by transferring it to the pre-wetting module, without transferring it to the plasma pretreatment module prior to transferring it to the first one of the one or more electroplating cells. In some cases, the controller is further configured to cause the apparatus to: (iii) process a third substrate by transferring it to the first one of the one or more electroplating cells without previously transferring it to the to the pre-wetting module or to the plasma pretreatment module.

In some implementations, the apparatus additionally includes an electrical power supply configured to control electrical current and/or voltage applied to substrates in the one or more electroplating cells. In certain embodiments, the controller is configured to ramp electrical current during electroplating a first one of the one or more electroplating cells.

These and other features of the disclosed embodiments will be described in more detail below, with reference to the associated drawings.

### BRIEF DESCRIPTION OF THE DRAWINGS

FIG. 1 is a cartoon illustration of a mechanism for bottom up electrofill of a feature in a substrate.

FIG. 2 is a polarization plot illustrating the suppression of metal deposition by an increasing amount of suppressor to an electroplating solution.

FIG. 3 is a flow chart illustrating various operations that may be performed before, during, and after electroplating cobalt, nickel, and/or alloys into features of a substrate.

FIGS. 4A and 4B present example hardware platforms on which at least some of the disclosed processes may be run.

FIG. 4C is a block diagram presenting a general example of an electroplating cell.

FIGS. 5-8 illustrate feature fill profiles obtained while designing a cobalt electroplating process for TSV features (CD 100 nm, Depth 1000 nm).

FIG. 9 presents illustrate feature fill profiles obtained while designing a nickel electroplating process for TSV features.

FIG. 10 provides an example illustrating the impact of a vacuum pre-wetting of deep TSV structures.

FIG. 11 illustrates process tuning for void free fill in larger TSV structures (6 by 60 micrometer features)

### DESCRIPTION OF CERTAIN EMBODIMENTS

### Introduction and Context

For some applications, through silicon vias (TSVs), micro-TSVs, and device contact channels (e.g., NAND contact channels) have been filled with tungsten metal through chemical vapor deposition or atomic layer deposition. However, some applications that currently use vapor deposited tungsten may employ metals other than tungsten and/or may use electrochemical deposition.

Examples of metals that may be used in place of tungsten (W) include cobalt (Co), nickel (Ni), Co—W alloys, Ni—W alloys, Co—Mo alloys, and Ni—Mo alloys. Cobalt or nickel may also be alloyed to each other as well as to other elements such as Cu, Ag, Au, Mn, Fe, Cr, Ru, P, B, C, N, Ir, Re, Pd, Pt, or any combination thereof. Any of these metals or alloys can be deposited by electrodeposition. Electrodeposited TSV or device contacts (e.g., NAND device contacts) may be deposited void free, meaning that the resulting interconnects or contacts have low resistance and good device performance.

This disclosure presents electrodeposition solutions, processes, apparatus, and systems for filling features with Co, Ni, and/or alloys thereof. In certain embodiments, at least some of the filled features have relatively high aspect ratios, such as at least about 5:1 or at least about 10:1. In some embodiments, the feature opening has a width or diameter of about 50 μm to 500 μm. The electrodeposition solutions, processes, and apparatus disclosed herein may be used in 3D technology, including technology developed or implemented in the future, scaling as other forms of electrodeposition have in past 2D scaling.

Currently TSV structures for certain applications such as global TSV and bond pad applications are filled with copper (Cu) because of its low resistivity and because these applications can manage challenges Cu presents. For developing global and intermediate TSV applications, however, W metal is being explored to replace Cu. W metal is forecast to be required for these future applications because of perceived potential issues of Cu integration into FEOL (front end of line) device layouts such as maximum current density, contamination, and electromigration lifetimes. In this disclosure, metals other than W and Cu are employed for TSV applications. As well, certain FEOL and device contact features may employ metals other than W. For example, while 3D NAND contacts are conventionally filled with W using vapor deposition methods, certain disclosed embodiments employ other metals for these contacts.

Employing cobalt, nickel, and/or certain alloys with these metals as alternatives to tungsten may offer one or more benefits such as any of the following:

Electromigration Resistance Exceeding Cu and Approaching or Matching W

Lower resistivities than similar features filled using vapor deposition processes, which may leave voids

Film Property Tuning Through Alloying and Post Process Anneal

Electroplating films provides high throughput (wafers per hour)

Electroplating films provides low cost wet deposition with reusable solutions.

### Terminology

The terms “semiconductor wafer,” “wafer,” “substrate,” and “wafer substrate” may be used interchangeably. Those of ordinary skill in the art understand that the term “partially fabricated integrated circuit” can refer to any of one or more devices on a semiconductor wafer during any of many stages of integrated circuit fabrication thereon. A wafer or substrate used in the semiconductor device industry typically has a diameter of 200 mm, or 300 mm, or 450 mm. This disclosure presents embodiments implemented on a “wafer.” It should be understood that such references to “wafer” extend to other types of work piece. A work piece may be of various shapes, sizes, and materials. Besides semiconductor wafers, examples of work pieces that may be employed in the disclosed embodiments include printed circuit boards, magnetic recording media, magnetic recording sensors, mirrors, optical elements, micro-mechanical devices, and the like.

A “semiconductor device fabrication operation” or “fabrication operation,” as used herein, is an operation performed during fabrication of semiconductor devices. Typically, the overall fabrication process includes multiple semiconductor device fabrication operations, each performed in its own semiconductor fabrication tool such as a plasma reactor, an electroplating cell, an annealing chamber, a chemical mechanical planarization tool, a wet etch tool, and the like. Categories of semiconductor device fabrication operations include subtractive processes, such as etch processes and planarization processes, and material additive processes, such as deposition processes (e.g., physical vapor deposition, chemical vapor deposition, atomic layer deposition, electrochemical deposition, electroless deposition).

The terms “process chamber,” “manufacturing equipment,” and “fabrication tool” refer to equipment in which a manufacturing process takes place. Manufacturing equipment often has a processing chamber in which the workpiece resides during processing. Typically, when in use, manufacturing equipment performs one or more semiconductor device fabrication operations. Examples of manufacturing equipment for semiconductor device fabrication include additive process reactors such as electroplating cells, physical vapor deposition reactors, chemical vapor deposition reactors, and atomic layer deposition reactors. Examples of subtractive process reactors include dry etch reactors (e.g., chemical and/or physical etch reactors), wet etch reactors, and ashers. Other types of manufacturing equipment include annealing chambers and cleaning devices.

The term “feature” as used herein may refer to an unfilled, partially filled, or completely filled recess on a substrate. Likewise, the term “through-silicon via” refers to unfilled, partially filled or completely filled recessed via formed in a silicon or other material substrate. Features may have different depths, different loadings, different shapes when viewed top down toward the substrate, and combinations thereof. In some embodiments, some features of the substrate may have round, oblong, or rectangular shapes when viewed from above. In some embodiments, at least some features on a substrate have an aspect ratio equal to or greater than about 2:1, equal to or greater than about 5:1, or equal to or greater than about 10:1.

Examples of feature dimensions are listed in Table 1. In some cases, features for 3D structures cover a range of openings of about 50 nm to 6 microns and feature depths of about 500 nm to 10 microns. For some TSV applications, notably micro-TSV applications, an example range of feature sizes includes an opening size of about 10-100 nm and depth of about 1-2 micrometers. In some implementations, feature dimensions fill the space between what is currently relatively low aspect ratio features (e.g., damascene features) and relatively higher aspect ratio features (e.g., TSV).

TABLE 1
Example feature dimensions

| | Dimension |
|---|---|
| Feature Diameter | about 0.05-6 um |
| Feature Pitch | about 0.5-4 um |
| Feature Depth | about 0.5-10 um |
| Feature Aspect Ratio | about 5:1-100:1 |

### Applications

The disclosed devices, electroplating solutions, electroplating methods, and apparatus may be applied to form interconnects for various applications, some of which may be characterized as “3D” applications. 3D applications generally employ multiple wafers or dies stacked vertically. In one example, logic devices are fabricated on one side of a wafer and connected by micro TSVs to memory or power lines on the opposite side of a wafer. In another example, different wafers are fabricated, one for logic and another for memory, and then the wafers are polished, stacked, and electrically connected through TSVs. Related applications are sometimes referred to as “2.5D applications.” These applications employ dies stacked onto interposer like structures to place multiple devices types into a single combined device.

Some applications are TSV applications such as micro TSV applications. A TSV is a via for an electrical connection passing completely through a semiconductor work piece, such as a silicon wafer or die. A typical TSV process involves forming TSV holes and depositing a conformal diffusion barrier and conductive seed layers on a substrate, followed by filling of the TSV holes with a metal. TSV holes typically have high aspect ratios which makes void-free deposition of copper into such structures a challenging task. TSVs may have aspect ratios of about 4:1 and greater, such as about 10:1 and greater, and even about 20:1 and greater (e.g., reaching about 30:1), with widths at opening of about 0.1 μm or greater, such as about 5 μm or greater, and depths of about 5 μm or greater, such as about 50 μm or greater, and about 100 μm or greater. Examples of TSVs include 5×50 μm and 10×100 μm features.

A micro TSV is TSV forming an interconnect spanning the thickness of a wafer or integrated circuit, electrically connecting one side of the structure to the other side of the structure. In some embodiments, a micro TSV interconnect electrically connects devices on different sides of a wafer or integrated circuit. As examples, the connected devices may be switches (e.g., transistors) or memory cells. In some applications, two sides of a wafer or integrated circuit have the same type of device (e.g., a transistor or memory cell). In some applications, one side of a wafer or integrated circuit has one type of device while the other side has a different type of device (e.g., transistors on one side of the device and memory cells on a different side of the device). Electrical connection between devices on the two sides of the wafer or integrated circuit may be made by an interconnect spanning the thickness of the wafer or integrated circuit.

In some cases, micro TSVs are used to provide lines for providing chip-level power from one side of a wafer or integrated circuit to the other side. In some cases, micro TSVs are used in integration schemes employing particularly small switches such as 3 nm devices or “gate all around” transistors such as FETs.

The geometric dimensions of micro TSVs are often smaller than those of conventional TSVs. In some embodiments, a micro TSV interconnect has a depth of about 1000 nm to about 2000 nm. In some cases, a micro TSV interconnect has an opening diameter or width of about 50 nm to about 150 nm. As examples, aspect ratios may be between about 5 and about 50.

Some applications form device contacts and are sometimes referred to as middle of line (MOL) or “metal 0” applications. These provide involve electrical connections directly to devices such as transistors or memory cells. As examples, the depth of the features in middle of line applications may be about 50 nm to about 500 nm, or about 100 nm to about 200 nm. In some cases, the opening width or diameter of the features in middle of line applications is about 5 nm to about 20 nm, or about 7 nm to about 10 nm. As examples, aspect ratios may be between about 2 and about 100.

In certain embodiments, 3D NAND devices have tungsten replaced with another metal such cobalt, nickel, and/or an alloy of either. In some cases, the non-W metal fills word lines. In some cases, the non-W metal fills 3D NAND contacts. These contacts may have dimensions comparable to large TSVs. The word lines may take the form of large plates, deposited at various levels.

The contact metal may be formed by removal of Si₃N₄ followed by electrofill with metal through a slit which is etched through an ONON stack. Examples of fabrication flows for fabricating 3D NAND structures with vapor deposited tungsten or other metal are described in PCT Patent Application No. PCT/US2020/013693, filed Jan. 15, 2020; and U.S. Patent Application Publication No. 20180144977, published May 24, 2018, each of which is incorporated herein by reference in its entirety.

In some embodiments, electrofilled Ni, Co, or alloys of either are used to fabricate transistor gates.

In certain embodiments, a substrate onto which Co, Ni, or an alloy is to be electrodeposited has a seed or liner layer. In some cases, the seed or liner layer comprises Co, Cu, Ni, NiB, NiBP, CoB, CoBP, CoZn, CuZn, NiZn, CoMn, CuMn, NiMn, or any combination thereof. In certain embodiments, a substrate onto which Co, Ni, or an alloy is to be electrodeposited has a diffusion barrier. Examples of materials that may serve as diffusion barriers include AlOx, WCN, Mo, MoOx, Zn, ZnOx, Mn, MnOx. In certain embodiments, the seed or liner layer is relatively thin, e.g., about 0.5 to 5 nm thick, on average. In certain embodiments, the seed or liner layer is relatively thick, e.g., about 50 to 500 nm thick, on average.

### Electroplating Solution Formulation

Various electroplating solution formulations may be employed for cobalt and/or nickel electrofill. Table 2 provides ranges for example formulations of inorganic components of cobalt electroplating solutions, nickel electroplating solutions, and alloy electroplating solutions for various applications such as those described herein. In various embodiments, Co or Ni electroplating solutions include a metal ion and boric acid. In some embodiments, the electroplating solution includes a cobalt and/or nickel ion, a counter anion, boric acid, and an additional acid (e.g., HCl). In certain embodiments, the electroplating solution has a pH in a range of about 2 to about 5. In certain embodiments, the electroplating solution has a pH in a range of about 2 to about 4. Note that in the tables below, metal salt concentrations are provided based on the mass of the metal ion only, not including the anion of the salt that provides the metal ion. So, for example, a cobalt salt concentration of 30 g/L has 30 grams of cobalt ion per liter of solution.

TABLE 2
Example Electroplating Solution Compositions

| | |
|---|---|
| Species | Concentration |

Cobalt Electroplating Solution

| | |
|---|---|
| Cobalt Salt | about 0.5-40 g/L |
| | (e.g., about 10 to about 40 g/L) |
| Chloride, Bromide Anion | about 0-200 ppm |
| Boric Acid | about 0-40 g/L |
| PH | about 2-5 |
| Solution Temperature | about 15-90 C. |

Nickel Electroplating Solution

| | |
|---|---|
| Nickel Salt | about 0.5-80 g/L |
| | (e.g., about 20 to about 80 g/L) |
| Chloride, Bromide Anion | about 0-200 ppm |
| Boric Acid | about 0-40 g/L |
| pH | about 2-5 |
| Solution Temperature | about 15-90 C. |

Cobalt-Nickel Electroplating Solution

| | |
|---|---|
| Cobalt Salt | about 0.5-40 g/L |
| | (e.g., about 10 to about 40 g/L) |
| Nickel Salt | about 0.5-80 g/L |
| | (e.g., about 20 to about 80 g/L) |
| Chloride, Bromide Anion | about 0-200 ppm |
| Boric Acid | about 0-40 g/L |
| pH | about 2-5 |
| Solution Temperature | about 15-90 C. |

Alloy Electroplating Solution

| | |
|---|---|
| Cobalt Salt | about 0.5-40 g/L |
| | (e.g., about 10 to about 40 g/L) |
| Nickel Salt | about 0.5-80 g/L |
| | (e.g., about 20 to about 80 g/L) |
| Alloy Metal Salt | about 0.01-30 g/L |
| Chloride, Bromide Anion | about 0-200 ppm |
| Boric Acid | about 0-40 g/L |
| PH | about 2-5 |
| Solution Temperature | about 15-90 C. |

In various embodiments, the concentration of the metal to be plated (e.g., cobalt or nickel) has a relatively higher concentration than employed in other integrated circuit electrofill applications for these metals. In certain embodiments, the concentration of cobalt ions in an electroplating solution is about 10 to about 40 g/L or about 20 to about 40 g/L. In certain embodiments, the concentration of nickel ions in an electroplating solution is about 20 to about 80 g/L or about 30 to about 80 g/L. In relatively large or deep features such as those encountered in some applications described herein, the deeper portions of the features are relatively inaccessible to the bulk solution (even when the electroplating cell has strong convection). As a consequence, these portions of the features may, during electroplating, become depleted of metal ions unless the electroplating solution has a relatively high concentration of metal ion. If deeper regions of a feature become depleted of metal ions while less deep regions still have available metal ions, voids may form in deeper regions of the electrofilled feature.

Further, features having relatively large volumes may require relatively faster deposition rates to maintain process throughput. Such higher electroplating rates and the associated high current densities can be supported with the relatively high metal ion concentration solutions described herein.

Examples of salt anions that may be used with the metal cations to be electro-reduced include sulfates, halides, borates, phosphates, and nitrates. In certain embodiments, the anion is or includes chloride and/or bromide.

To electroplate an alloy, the electroplating solution includes at least two metal ions. Electroplating solutions for depositing a metal alloy may employ metal salts that reduce within a similar electrochemical process window. Examples of metal alloys that can be created by applying electrical potential to solutions of Co and/or Ni containing other elements such as Cu, Ag, Au, Mn, Fe, Cr, Ru, P, B, C, N, Mo, Ir, Re, Pd, Pt. In some cases, the metal salts in the electroplating solution are chosen to electroplate an alloy of Co and W alloy, an alloy of Ni and W, an alloy of Co and Mo, or an alloy of Ni and Mo. In some implementations, an alloy is deposited from an electroplating solution having a complexing ligand or other additive that selectively inhibits or activates electrodeposition of one metal relative to another in the alloy. For example, if thermodynamics and/or kinetics favors deposition of a first metal over a second metal at a particular operating potential, the electroplating solution may include a complexing ligand that retards the deposition of the first metal more than it retards the deposition of the second metal. In this way, and in other ways having similar effect, an electrochemical window is chosen that deposits alloy metals in desired ratios.

In embodiments employing bottom-up fill in patterned features, one or more organic additives may be added to the electroplating solution. Such additives alter the deposition rate of metal at the feature bottom and on the field. Table 3 provides example ranges of organic additives in electroplating solutions to generate bottom up fill in the high aspect ratio features. Of course, the concentrations may vary within these ranges depending on the chemical additive employed. In general, these ranges apply to any of the example compounds described below.

TABLE 3
Example organic additives for Electroplating Solution and/or Pre-wetting Solution.

| Species | Concentration |
|---|---|
| Accelerator | 0-about 200 ppm |
| Suppressor | 0-about 200 ppm |
| Leveler | 0-about 200 ppm |
| Complexation Agent | 0-about 30 g/L |

In various embodiments, bottom up fill is facilitated by establishing suppressor and/or hydrogen ion concentration gradients within features, from a field region (higher concentration) to the bottom or lower recess regions of features (lower concentration). Lower concentrations of suppressor and/or hydrogen ions at and/or near the bottom of features promote faster electroplating in these regions compared to electroplating in the field regions or upper regions of the features (those regions of the features that are closer to the field regions).

Because cobalt and certain other metals do not electroplate with 100% current efficiency from acidic electroplating solutions, the local concentration of hydrogen ions (and corresponding local pH) can have a strong impact on the relative rate of metal electroplating. Regions with relatively higher hydrogen ion concentration allow the hydrogen evolution reaction to significantly compete with the metal deposition reaction, which results in a relatively slower rate of metal deposition. In contrast, regions with relatively lower hydrogen ion concentration produce relatively less elemental hydrogen and thereby have higher metal deposition current efficiencies and faster rates of metal deposition. A hydrogen ion gradient may exist within a feature due to various physical and chemical factors. For example, geometrically, there is relatively more substrate surface area per unit volume than in the field region. As a consequence, there is more reaction occurring per unit volume within a feature than outside a feature. Further, convection of the bulk electroplating solution may easily supply hydrogen ions to the field regions but not so easily supply hydrogen ions to features, particularly deeply recessed portions of the features. Hence, the hydrogen ion concentration tends to remain lower within features, particularly deep regions of features, than in field regions or upper portions of features.

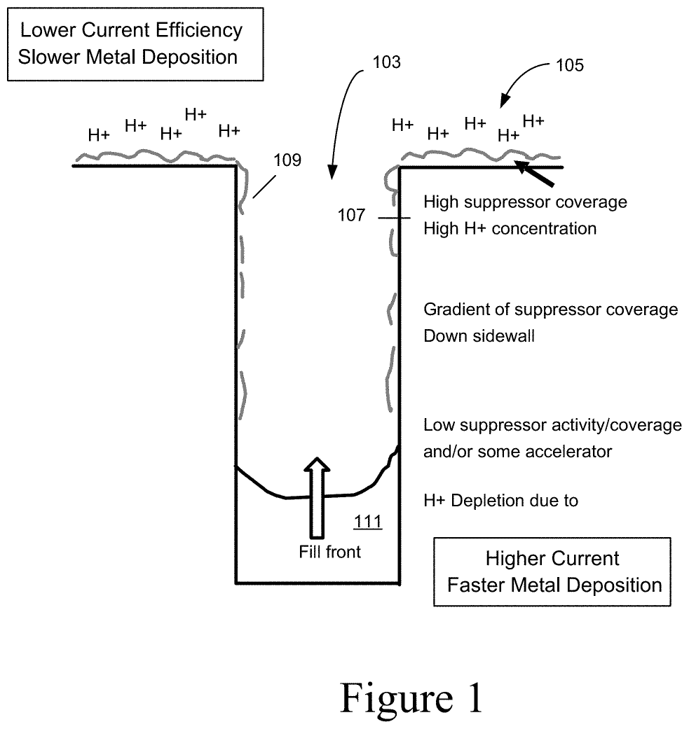

FIG. 1 illustrates how solution components may interplay and drive bottom-up fill in a recessed feature 103. The feature field 105 and the upper sidewalls 107 are relatively passivated, and electroplating is suppressed by the accumulation of organic additives 109. Hydrogen ion adsorption and/or mass transport to the field may also lower the deposition rate of metal on the field due to a competing hydrogen reduction reaction. Overall this leads to slower cobalt deposition 111 at the top of the feature and allows for void free bottom up fill to be obtained in a range of feature sizes. The difference in the rate of electroplating at the feature bottom compared to the rate of electroplating on the field can be increased by an organic additive, the breakdown of an organic additive, or the consumption and/or depletion of hydrogen. To setup void free fill typically a concentration gradient of organic additive coverage and/or hydrogen ion in the feature may be established. This may be accomplished by setting process parameters such as initial solution concentrations (e.g., pH), mass transport (RPM of the substrate being plated) and electroplating current. A wide range of operating conditions can support the hydrogen ion gradient. These may be determined empirically, by modelling the underlying mass transport and other relevant physical conditions, or a combination of both approaches. The gradient is a function of the plating current applied, which drives the consumption of hydrogen ions. As indicated, the gradient forms due to the geometry of the feature, which provides a greater driving force for consumption of hydrogen ions at the base of a feature than in the field regions. In certain embodiments, the starting composition of the electroplating bath has a hydrogen ion concentration of about 0.00001 to 6.4M.

In certain embodiments, the electroplating solution contains, in addition to cobalt and/or nickel salt, a suppressor. In some implementations, the electroplating solution contains a suppressor as the only additive, with no accelerator or leveler. In some implementations, the electroplating solution contains a suppressor along with an accelerator and optionally with a leveler. In some implementations, the electroplating solution contains a suppressor along with a leveler.

In general, suppressing molecules or “suppressors” are molecules that make metal ions reduce less readily onto the substrate. One mechanism by which this may occur is through chemisorption of a molecule on the substrate surface which either sterically hinders the approach of metal ions or occupies reaction sites on the substrate. During the electroplating process, the chosen suppressor interacts with both the unplated substrate surface (e.g., a seed layer) and the partially plated metal film.

Suppressors (either alone or in combination with other electroplating solution additives) are surface-kinetic polarizing compounds that induce a significant increase in the voltage drop across the substrate-electrolyte interface. In some cases, a halide ion acts as a chemisorbed-bridge between the suppressor molecules and the substrate surface. The suppressor both (1) increases the local polarization of the substrate surface at regions where the suppressor is present relative to regions where the suppressor is absent (or present at a relatively lower concentration), and (2) increases the polarization of the substrate surface generally. The increased polarization (local and/or general) corresponds to increased resistivity/impedance and therefore slower plating at a particular applied potential.

Suppressors may be relatively large molecules, and in some instances they are polymeric (e.g., polyethylene oxide (PEO), polypropylene oxide (PPO), polyethylene glycol (PEG), polypropylene glycol (PPG), other general polyalkylene glycol (PAG) polymers, copolymers (including block copolymers) of any of these, and the like). These polymers and copolymers may be further functionalized, with the functional groups that may improve solubility or interaction with the substrate. Some examples of functionalized suppressors include polyethylene oxides and polypropylene oxides with sulfur and/or nitrogen-containing functional groups. The suppressors can have linear chain structures or branch structures or both. A particular class of suppressor molecules includes the organic chemisorption corrosion inhibitors. Suppressor molecules with various molecular weights may co-exist in a suppressor solution.

Due in part to suppressors' large size, the diffusion of these compounds into a recessed feature can be relatively slow compared to other electroplating solution components.

In some cases, suppressors are not significantly incorporated into the deposited film, though they may slowly degrade over time by electrolysis or chemical decomposition in the electroplating solution.

Example classes of suppressors include but are not limited to ether derivatives, ester derivatives, glycol derivatives, thiazole compounds, pyridine compounds and derivatives, and polymeric compounds.

Examples of suppressor ethers include nonylphenolpolyglycol ether, polyethylene glycoldimethyl ether, octandiolbis (polyalkylene glycol ether), octanolpolyakylene glycol ether, polyethylene glycoldimethyl ether, and stearyl alcohol polyglycol ether.

Examples of suppressor esters include oleic acid polyglycol ester; and stearic acid polyglycol ester.

Examples of suppressor glycols include polyethylene propylene glycol, polyethylene glycol, polyoxypropylene glycol; and polypropylene glycol. Examples of suppressor thiazoles include 2-amino-5-(ethylthio)-1,3,4-thiadiazole, 6-amino-2-mercaptobenzothiazole, and 2-mercaptobenzothiazole.

Examples of suppressor pyridine compounds include 2-aminopyridine, 3-hydroxypyridine-4-sulfonic acid, purine, 2,2′-dipyridyl disulfide, 3-pyridine sulfonic acid, and 3-(1-pyridino)-1-propanesulfonate.

Examples of other suppressors include carboxymethylcellulose, polyethyleneimine, polyvinyl alcohol, polyethylene oxide; ethylene oxide-propylene oxide copolymers, butyl alcohol-ethylene oxide-propylene oxide copolymers; 2-mercapto-5-benzimidazolesulfonic acid; 2-mercaptobenzimidazole (MBI), benzotriazole, o-benzoic sulfimide (saccharine), benzethonium chloride, thonzonium bromide, 1-benzylimidazole, and 2-thiazoline-2-thiol. Examples of other polymeric compounds include polyvinylpyrrolidone (PVP), polyacrylamide, and poly(2-ethyl-2-oxazolone).

In certain embodiments, any one or more of the above suppressors may be provided in any of the electroplating solutions disclosed herein in concentrations of about 1-10,000 ppm.

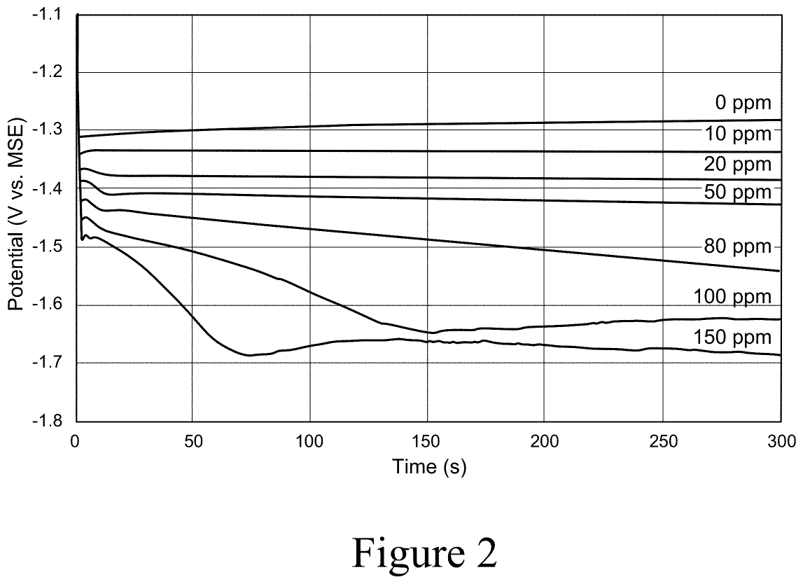

FIG. 2 provides polarization plots illustrating the suppression of nickel metal deposition by an increasing amount of suppressor to an electroplating solution. If a gradient of the same compound exists throughout a patterned feature due to diffusion, mass transport, or coverage it can generating bottom up fill by having a gradient of suppressor coverage through the feature depth. As less organic additive exists down into the feature more metal deposition will occur as the surface is less polarized or passivated.

In some applications an accelerator is included in the electroplating solution. Accelerator may accumulate preferentially at the bottom of features and assist in catalyzing metal deposition to support bottom-up fill.

Accelerator molecules can make metal ions reduce more readily onto the substrate relative to a suppressed surface, e.g., a surface having suppressor species attached. It is believed that accelerators (either alone or in combination with other electroplating solution additives) locally reduce the polarization effect associated with the presence of suppressors, and thereby locally increase the electrodeposition rate. Accelerator molecules may be used based in part on their ability to sustain higher rates of plating in areas where these high rates begin (vis-á-vis area where suppressor dominates the polarization characteristic).

Electrochemically, accelerators decrease in the magnitude of polarization required to deposit metal onto a suppressed substrate. Since suppressor molecules are more inhibiting than accelerators, one possible mechanism of action of suppressors involves competition with accelerators for binding sites, resulting in higher current densities in those area in which suppressor is supplanted by accelerator.

The reduced polarization effect is most pronounced in regions of the substrate surface where the accelerator is most concentrated (i.e., the polarization is reduced as a function of the local surface concentration of adsorbed accelerator or the ratio of accelerator to suppressor). Although the accelerator may become strongly adsorbed to the substrate surface and may be generally laterally-surface immobile as a result of the plating reactions, in some embodiments, the accelerator is not significantly incorporated into the film. In such cases, the accelerator may remain on the surface as metal is deposited. In some cases, as a recess is filled, the local accelerator concentration increases on the surface within the recess. Accelerators tend to be smaller molecules and exhibit faster diffusion into recessed features, as compared to suppressors.

Examples of classes of accelerators include but are not limited to esters such as sulfonic acid esters, salts such as sulfonic acid salts, mercapto compounds, and triazole compounds.

Examples of accelerator esters include N,N-dimethyl-dithiocarbamic acid(−3-sulfopropyl)ester, 3-mercapto-propylsulfonic acid (3-sulfopropyl)ester; carbonic acid-dithio-o-ethylester-s-ester with 3-mercapto-1-propane sulfonic acid potassium salt, N,N-dimethyl-dithiocarbamic acid-(3-sulfoethyl)ester, 3-mercapto-ethyl propylsulfonic acid(3-sulfoethyl)ester, and carbonic acid-dithio-o-ethyl ester-s-ester.

Examples of accelerator salts include 3-mercapto-propylsulfonic acid sodium salt, 3-(benzothiazolyl-s-thio)propyl sulfonic acid sodium salt; and 3-mercapto-ethylsulfonic acid sodium salt.

Examples of accelerator mercapto compounds include mercaptopropyl sulfonic acid, 1,3,4-thiadiazole-2,5-dithiol, 2-mercapto-5-benzimidazolesulfonic acid, 3-amino-5-mercapto-1,2,4-triazole, 5-amino-2-mercaptobenzimidazole, and 2-mercaptotriazole.

Examples of accelerator triazole compounds include 1,2,4-triazole, and 1-H-benzotriazole sulfonic acid.

Examples of other accelerators include bis-sulfopropyl disulfide, pyridinium propyl sulfobetaine, 1-sodium-3-mercaptopropane-1-sulfonate, pyridinium ethyl sulfobetaine; thiourea, bis-3-sulfopropyl disulfide, thiourea, poly(N-isopropylacrylamide), and thiazole.

In certain embodiments, any of these accelerators disclosed herein may be present in an electroplating solution at a concentration of about 1-10,000 ppm.

For some layers, a range of feature densities exist. In regions of dense arrays less suppressor adsorbs onto the surface due the increased number of patterned features. This means as fill completes the metal deposited in this region has less suppressed deposition and will electroplate at a faster rate than isolated regions. This can result in variations in electroplated metal topography that cause issues during chemical mechanical planarization steps. To minimize topography variations a leveler compound can be added to solutions to even deposition rates across dense and isolated patterns.

Leveling molecules may act by limiting the depolarizing effect of an accelerating molecule. Levelers may perform this function especially in exposed portions of a substrate, such the field region of a wafer being processed, and at the side walls of a feature. A leveler may act by desorbing or displacing the accelerator, preventing it from effectively competing with a suppressor for binding sites, burying it in the plated film, or chemically degrading it. The local concentration of levelers is determined to some degree by mass transport. It is believed that in many cases the leveler reacts or is consumed at the substrate surface at a rate that is at or near a diffusion limited rate, and therefore, a continuous supply of leveler may maintain uniform plating conditions over time. Compounds which do not principally act by adsorbing onto a substrate surface are not considered levelers.

Leveler compounds are generally classified as such based on their electrochemical function and impact and do not require specific chemical structure or formulation. However, levelers often contain one or more nitrogen, amine, imide or imidazole, and may also contain sulfur functional groups. Certain levelers include one or more five and six member rings and/or conjugated organic compound derivatives. Nitrogen groups may form part of the ring structure.

Example chemical classes of levelers include alkyl, aryl, and heterocyclic amines, epoxides, aromatic nitrogen heterocycles, benzothiazole derivatives, cyclic imides, benzoic acid derivatives, and polymeric compounds.

In amine-containing levelers, the amines may be primary, secondary or tertiary alkyl amines. Furthermore, the amine may be an aryl amine or a heterocyclic amine. Example amines include, but are not limited to, dialkylamines, trialkylamines, arylalkylamines, triazoles, imidazole, triazole, tetrazole, benzimidazole, benzotriazole, piperidine, morpholines, piperazine, pyridine, oxazole, benzoxazole, pyrimidine, quinoline, and isoquinoline. In certain embodiments, the leveler is an imidazole and/or pyridine. Other examples of levelers include Janus Green B and Prussian Blue.

In certain embodiments, a leveler is an aromatic nitrogen heterocycle. Example aromatic nitrogen heterocycle levelers include 2,2-bipyridine, 2-hydroxy-pyridine, 8-hydroxyquinoline, picoline, pyrrole, thiazole, isoxazole, 6-H-1,2,5-thiadiazine, azocine, azecine, indole, isoindole, purine, carbazole, pyrazine, pyridazine, acridine, indolizine, and pyrazole.

In certain embodiments, a leveler is benzothiazole or a derivative thereof. Examples of benzothiazole derivative levelers include o-benzoic sulfimide (Saccharin), benzothiazole, 2-aminobenzothiazole, 2-hydroxy benzothiazoles, 2-mercaptobenzothiazole, 2-methylthiobenzothiazole, 2,2′-dithiobis(benzothiazole), 2-(2-hydroxyphenyl)benzothiazole, methabenzthiazuron, 2 (4-aminophenyl)benzothiazole.

In certain embodiments, a leveler is a cyclic imide. Examples of cyclic imide levelers include phthalimide, N-methylphthalimide, N-ethylphthalimide, N-bromophthalimide, N-chlorophthalimide, 3-hydroxyisoindolinone, maleimide, 2,3-dibromomaleimide, N-methyl succinimide, N-phenyl maleimide, N-maleoyl-b-alanine, and pyromellitic diimide.

In certain embodiments, a leveler is benzoic acid or a derivative thereof. Examples of benzoic acid derivative levelers include benzamide, substituted benzamides, benzoate salts, alkyl benzoate esters, hydroxybenzoate esters, benzyl alcohol, benzaldehyde, benzophenone, and benzoguanamine.

Leveler compounds may also include ethoxide groups. For example, the leveler may include a general backbone similar to that found in polyethylene glycol or polyethelene oxide, with, e.g., fragments of amine functionally inserted over the chain (e.g., Janus Green B).

In certain embodiments, a leveler is an epoxide. Example epoxides include, but are not limited to, epihalohydrins such as epichlorohydrin and epibromohydrin, and polyepoxide compounds. Polyepoxide compounds having two or more epoxide moieties joined together by an ether-containing linkage are used in some electroplating solutions.

Some leveler compounds are polymeric, while others are not. Example polymeric leveler compounds include, but are not limited to, polyethylenimine, polyamidoamines, and reaction products of an amine with various oxygen epoxides or sulfides. Another example a polymeric leveler is polyvinylpyrrolidone (PVP). One example of a non-polymeric leveler is 6-mercapto-hexanol.

### Electroplating Process Parameters

In certain embodiments, the electroplating process is performed at a temperature in the range of about 18° C. to about 90° C. In certain embodiments, the electroplating process is performed at a temperature in the range of about 25° C. to about 50° C. A relatively high electroplating temperature may support relatively fast electrofill rates which may be useful when filling features having relatively high volumes as is the case in some of certain applications described herein such as TSV applications.

In certain embodiments, the electroplating cell's current and/or voltage is ramped over some or all of the course of feature filling. Electrical current ramping may allow maintenance of a hydrogen ion concentration gradient that facilitates bottom up fill. As a feature fills with metal, the driving force (at the top of the filling metal) for local hydrogen ion depletion decreases. At and near the top of a feature, hydrogen ions are more readily swept in from the bulk solution by convection and the geometric considerations favoring hydrogen ion depletion (greater reaction surface area per unit volume) decrease. Therefore, increasing the electrical current density within features may help maintain a hydrogen ion concentration gradient within the unfilled regions of partially filled features.

In certain embodiments, the current density on a substrate is ramped at a rate of about 0.002 mA/cm²·s to about 0.02 mA/cm² s. In certain embodiments, current at the beginning of the bulk electroplating process is about 0.15 to 1.8 mA/cm². In certain embodiments, the current at the end of the bulk electroplating process is about 1 to 5 mA/cm². The end of the bulk electroplating process may be when all or nearly all the features are fully filled to the level f the field region and/or when substantial overburden forms. The actual values depend, of course, on the application. As explained, current density is ramped to consume hydrogen ions at the feature bottoms and setup a gradient that drives fill. Lower pH applications require higher starting current densities to consume sufficient hydrogen ion to establish a gradient. The current density values provided herein are determined using the geometric planar face of the plating surface of the substrate. In other words, the current density values are determined assuming the plating surface is perfectly flat and without additional surface area created by the features.

### Pre- and Post-Electroplating Processing

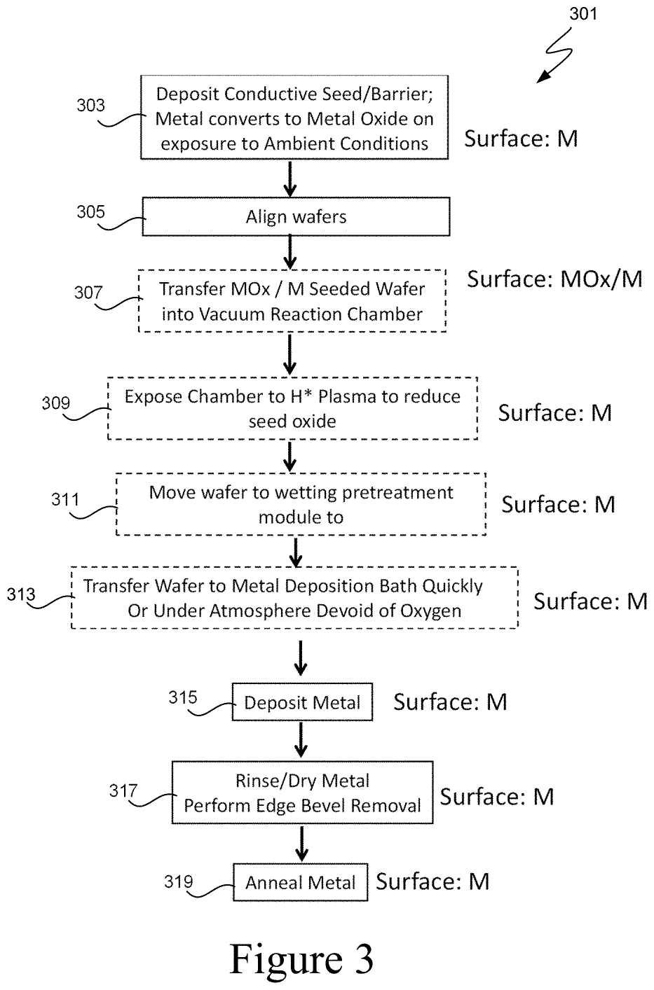

FIG. 3 presents an example process flow for electrodeposition on an electroplating platform. The operations in dashed blocks are optional steps performed in a vacuum pretreatment module (VPM). A liquid pretreatment module may be used to improve fill into feature bottom is dependent on feature depth/feature size.

FIG. 3 depicts a process 301 for depositing metal in a contact via, through silicon via, or other interconnect channel. As shown, process 301 begins by depositing a conductive seed and/or diffusion barrier layer on a substrate comprising multiple features, such as high aspect ratio features. See operation 303. As explained elsewhere herein, in certain embodiments, substrate features may define micro TSV holes or device contact holes such as contact holes for 3D NAND devices. In certain embodiments, the conductive seed layer and/or barrier layer are deposited by a vapor deposition technique such as a chemical vapor deposition or by a physical vapor deposition technique such as sputtering.

After the conductive seed and or diffusion barrier layers are deposited on the substrate, as illustrated at block 303, the substrate may be aligned as illustrated at a block 305. The alignment ensures that substrates go through the tool modules in a reproducible way. This facilitates trouble shooting. For example, if a pattern is observed on the right side of a wafer, this might point to a particular component or feature on the tool that is causing the issue. The alignment may be used in wafer metrology tools to line up wafer locations on a grid and compare wafer to wafer metrology results. In certain embodiments, alignment is performed to ensure that certain features of a substrate are positioned properly vis-à-vis corresponding features on a fabrication tool. For example, because wafers sometime have a notch or other variation on their perimeters, the wafers may need to be azimuthally aligned a seal on a wafer holder of an electroplating tool to ensure that electroplating solution does not flood regions above the wafer.

As explained elsewhere herein, a conductive seed layer may be susceptible to oxidation upon exposure to ambient conditions. And in various embodiments, after the seed layer is deposited by PVD or a vapor deposition technique, it is exposed to atmospheric conditions. During this exposure, some of the conductive seed, which is often a metal layer, may oxidize to form metal oxide on or in the metal seed layer.

In order to convert some metal oxide back to metal and/or to reduce or mitigate the conversion of metal seed layer to metal oxide, the substrate is optionally chemically reduced or exposed to chemically reducing conditions. For example, as illustrated, the substrate may be placed in a vacuum reaction chamber as illustrated at operation 307. In the depicted embodiment, the substrate in the vacuum reaction chamber is exposed to a hydrogen-containing plasma, which reduces any oxide formed on the metal seed layer back to elemental metal. See block 309. Note that as with the operation in block 307, the operation in block 309 is optional. In other words, in certain embodiments, a metal seed layer need not be exposed to a reducing plasma.

After optional operations 307 and 309 are completed, the wafer is optionally moved to a wetting pretreatment module as illustrated at operation 311. As explained elsewhere herein, a wetting pretreatment module pre-wets a substrate before electroplating. A pre-wetting solution may contain one or more components of the electroplating solution. By pre-wetting the substrate in the pre-wetting module, the process wets unfilled features with a liquid solution and removes air gaps or other gas voids that might exist within the features prior to electroplating. As explained, air or other gas voids within features can effectively block filling portions of the features with metal.

After the substrate is optionally exposed to a pre-wetting operation 311, the substrate is transferred to a metal deposition electroplating bath. See block 313. This operation typically takes place quickly (e.g., at most about 60 s), in order to avoid exposure to atmospheric oxygen.

After the substrate is immersed in the electroplating solution, it is exposed to a reducing electrical potential (cathodic) under which metal ions in the electric playing solution deposit as a metal layer on the surface of the substrate. As explained elsewhere herein, the electroplating solution and associated electroplating deposition conditions deposit the metal in the features of the substrate in a bottom up fill mechanism, which fills the features beginning at the bottom. Bottom up fill reduces the production of voids and seams in the electroplated metal within the features.

After the electro fill process is completed in operation 315, the substrate is removed from the electroplating solution and rinsed and dried and optionally exposed to an edge bevel removal process. See operation or block 317. Finally, as illustrated at a block 319, the substrate is optionally annealed to modify the electroplated metal.

### Apparatus and System

Various hardware systems may be employed to electroplate cobalt, nickel, and/or alloys thereof, as disclosed herein. The hardware may include one or more electroplating cells along with one or more associated modules, any of which may be configured to perform pre- or post-electroplating operations. In some embodiments, the cells and modules are arranged in a single chassis or frame. In some embodiments, the cells and modules are arranged to allow multiple different pre-processing options, which may include, e.g., (1) conductive seed or liner preservation or recovery together with substrate pre-wetting, (2) only substrate pre-wetting without seed or liner preservation or recovery, or (3) no pre-wetting or seed/liner preservation. Option 1 may be appropriate for substrates having relatively high aspect ratio and/or deep features along with thin seed or liner and/or long exposure to ambient conditions prior to electroplating. Thin seed layers or liners are susceptible to oxidation and concomitant void formation during electroplating, which issue can be remedied by seed/liner recovery operations. Deep and/or high aspect ratio features are susceptible to holding air pockets and concomitant void formation during electroplating, which issue can be remedied by pre-wetting. Option 2 may be appropriate for substrates having robust seed or liner layers but deep or high aspect ratio features. Option 3 may be appropriate for substrates having robust seed or liner layers and relatively shallow and/or low aspect ratio features.

Thin seed that is exposed to atmospheric oxygen and water vapor may rapidly oxidize. If wafers wait for a few hours in queue for electroplating, sidewall voiding may occur due to oxide dissolution. Where appropriate, such as when there are long wafer fabrication queue times and/or the seed layer is relatively thin, metal oxide may be converted back to metal using a pretreatment module that chemically reduces oxide on the seed layer to metal. Such pretreatments may be dry or wet processes. One example of a dry treatment is plasma process performed in a plasma vacuum pretreatment module. In certain embodiments, the vacuum pretreatment is performed using a plasma comprising hydrogen. Examples of methods and apparatus for conducting chemically reducing operations on seed layers are described in the following patent documents which are incorporated herein by reference in their entireties: U.S. Pat. No. 9,070,750, issued Jun. 30, 2015, U.S. Pat. No. 9,865,501, issued Jan. 9, 2018, US Patent Application Publication No. 20150299886, published Oct. 22, 2015, and US Patent Application Publication No. 20150376792, published Dec. 31, 2015.

In some embodiments, a dry pretreatment employs a plasma to alter the surface of the substrate. A plasma process may reduce oxide on the surface of the substrate. Some such processes employ a reducing plasma. In certain embodiments, the plasma is generated from a gas mixture of hydrogen and a carrier, such as helium. The pressure of the gas mixture may be about 0.1 to 10 Torr, for example about 1 to 3 Torr. A plasma is struck in the gas mixture using, e.g., radio frequency energy input having a power of, e.g., about 0.25 to 5 kW, for example about 1 to 3 kW. In certain embodiments, a plasma generation chamber may be separated from the substrate by a perforated barrier (e.g., a showerhead) which may be grounded and cooled to decrease ion flux while permitting hydrogen radical flux. During processing, the substrate may rest on a heated pedestal under a showerhead. Examples of remote plasma systems are described in U.S. Pat. No. 9,865,501, issued Jan. 9, 2018, which is incorporated herein by reference in its entirety.

In certain plasma pretreatment embodiments, the temperature of substrate (optionally through control of the pedestal temperature) is held at about 30 degrees Celsius to 600 degrees Celsius, for example about 75 to 250 degrees Celsius. In certain embodiments, a plasma pretreatment is performed for a period of about 30 seconds to 60 minutes. The substrate may be cooled before being allowed to contact normal atmosphere.

If the seed is sufficiently thick, then oxide dissolution may not be an issue and the plasma or other type reduction operation may not be needed. Because the electroplating solutions, processes, and apparatus described herein are useful for processing a range of different substrate types, they may be employed to process some substrates having relatively thin or damaged seed layers, and as well to process some substrates having features with relatively thick and/or robust seed layers.

In addition to or as an alternative to the seed layer reduction operation, a substrate may be subjected to a pre-wetting operation. Such pretreatment operation may be utilized, for example, on features deeper than about 1 micron. In certain embodiments, pre-wetting is performed under vacuum. This operation may evacuate air bubbles trapped in the features that generate large voided features if not removed. In certain embodiments, a substrate is pre-wetted with purified water, purified water with one or more organic electroplating additives, ethyl alcohol, or an ethyl alcohol/purified water solution. The organic additive used for pre-wetting may be a suppressor or wetting agent such as any of those described herein. An organic additive of relatively high concentration may be added to the prewet module solution in order to assist in wetting and suppression of electroplating on the field. Examples of methods and apparatus for conducting substrate pre-wetting are described in the following patent documents which are incorporated herein by reference in their entireties: U.S. Patent Application Publication No. 20100320081; U.S. Patent Application Publication No. 2016/0273117 by N. Doubina et. al.; U.S. Pat. No. 9,455,139 by Blackman; and U.S. Pat. No. 7,232,513 by E. G. Webb et.

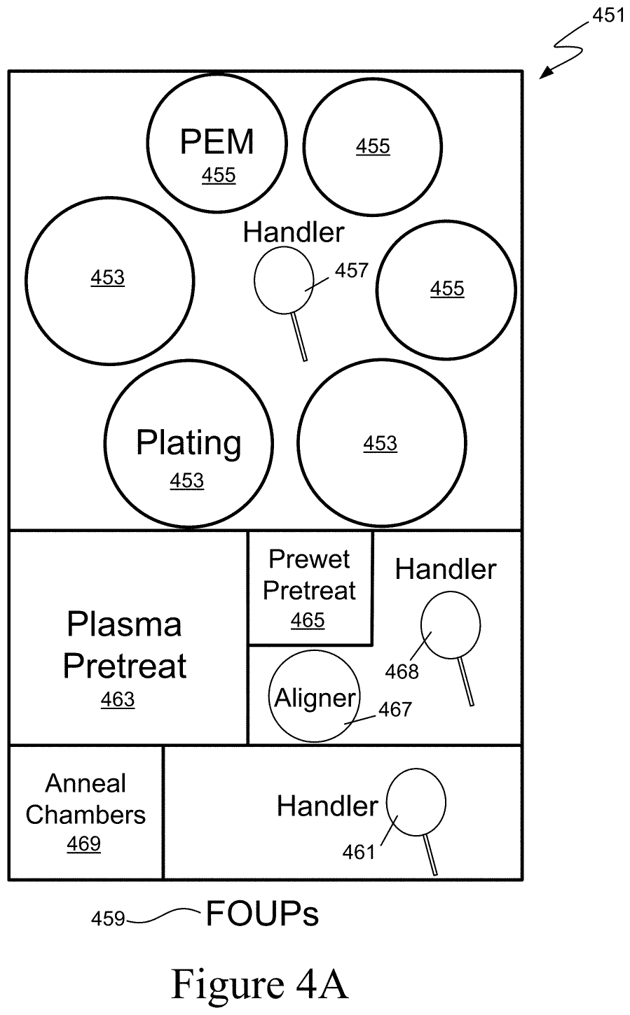

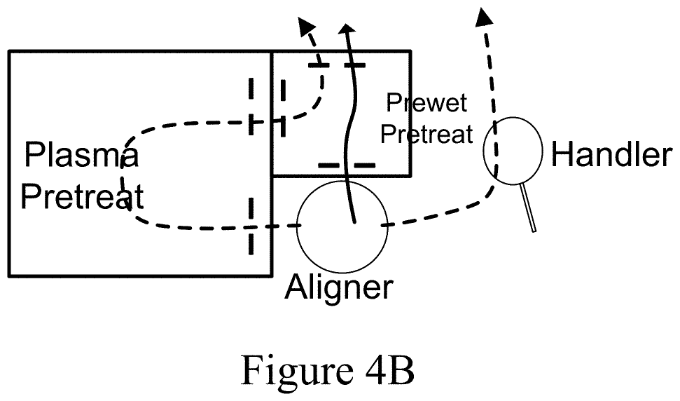

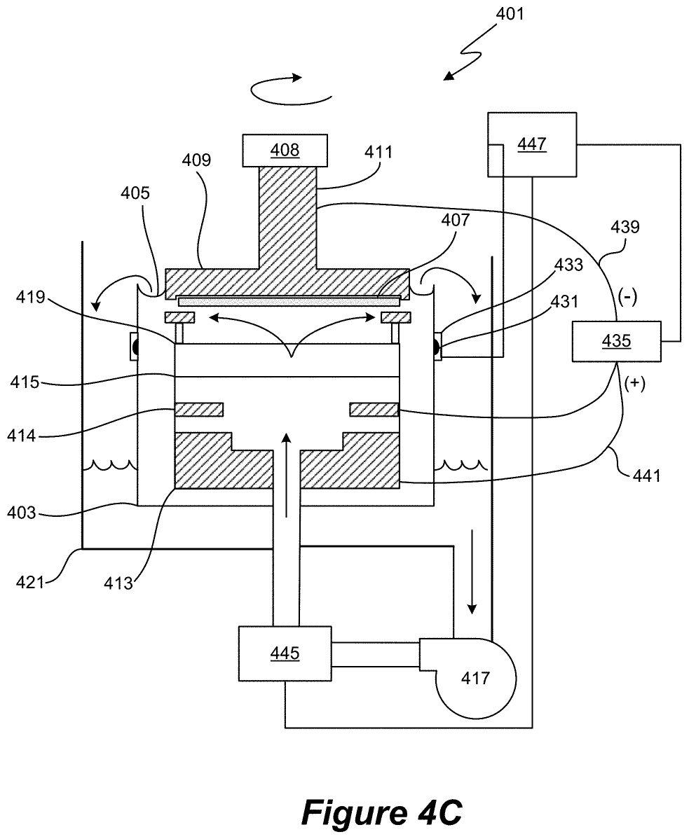

FIGS. 4A and 4B present example hardware platforms on which at least some of the disclosed processes may be run. Other embodiments may include additional electroplating cells, robotic handlers, and/or modules, and/or a different format of cells, modules, robotic handlers, and the like. In certain embodiments, the platform is configured to process substrates per one of the processes covered within the flow chart of FIG. 3.

Upstream from the electroplating tool, wafers may be prepared by, e.g., etching patterns in a dielectric layer or layers and/or depositing diffusion barrier and/or seed layers.

An electroplating tool or platform 451 diagramed in FIG. 4A includes multiple electroplating cells 453 (three in this example) and multiple post electroplating modules 455 (three in this example). A handler such as 457 such as a robot configured to move wafers into and out of the electroplating cells 453 and the post electroplating modules 455. Collectively, the electroplating cells 453 and the post electroplating modules 455 may form part of a “back end” of platform 451. A front end of the platform 451 may interface with systems or queues outside of the platform. For example, substrates that are to be electroplated may be fed to the platform 451 through a front end loading FOUP(s) 459. The tool may be configured such that substrates from the FOUP(s) 459 may be brought to a main substrate processing area via a front-end handler 461 (e.g., a robot) that can retract and move a substrate driven in multiple dimensions. In the depicted embodiment, there are two front-end accessible stations, a plasma pretreatment module463 and a prewet pretreatment module 465. An aligner 467 and a handler 468 are associated with the prewet pretreatment module 465. Electroplating platform 451 also includes one or more anneal chambers 469 configured heat and anneal substrates after electroplating.

As depicted, in some embodiments, a plasma pretreatment module is larger than an anneal module and/or an anneal module is larger than a pre-wetting module. In certain embodiments, a plasma module includes multiple substrate processing stations, which may allow parallel pretreatments. In some cases, a pre-wetting module has only a single station for substrate processing. This difference may, at least partially, account for the relative size difference of these modules. Arranging the anneal, pre-wetting, and plasma processing modules within the chassis or frame of the platform in a manner that accounts for their relative sizes allows for a compact platform design.

The electrodeposition apparatus 451 is shown schematically looking top down in FIG. 4A. In some embodiments, two or more levels are “stacked” on top of each other, each optionally having identical or different types of processing stations.

In certain embodiments, a wetting pretreat module may be arranged so that substrates may go through plasma pretreatment and into the prewet module or wafers may go directly into the prewet module from a FOUP (or other substrate holding component) depending on the incoming wafer requirements.

Various post-electroplating operations may be performed in appropriately configured modules. These include, for example, any one or more of spin-rinsing, spin-drying, metal and/or silicon wet etching, and edge bevel removal. As indicated, an anneal module may be employed as a post-electroplating module. Annealing may be employed to grow grains of electrodeposited metal and thereby reduce resistance of the metal.

In certain embodiments, a front section of an electroplating platform may be configured in such a way to allow for flexibility in the pretreatments done on substrates depending on the types of structures to be electroplated on the platform. For example, as mentioned, different types of substrates may be subject to pre-wetting and/or plasma treatment.

The electroplating platform may or may not include a load lock suitable for transferring the substrate from one pre-treatment module to another or from a pre-treatment module to an electroplating cell under vacuum. As mentioned, a prewet module may be configured to operate at a pressure lower than atmospheric pressure. In certain embodiments, an electroplating system is configured to transfer substrates, directly after pre-wetting, to electroplating cells for metal deposition. In some cases, a system is configured to substrates in a manner that retains a thin film of water on the wafer surface to minimize entrapment of air in the structure. In the tool configuration shown in FIG. 4A, some substrates may be transferred directly to electroplating cells, in a manner that bypasses pre-wetting. Such operation may be appropriate when the pre-wetting step is not necessary, which may be the case for certain wafer lots.

FIG. 4B illustrates three paths that substrates may take through pre-processing modules in a tool. The depicted paths are no pretreatment 403, prewet only 405, and seed reduction (e.g., plasma processing) together with prewet 407. In some implementations, there may another path: seed reduction (e.g., plasma processing).

In the example of FIG. 4B, two of the paths do not employ a handler because the first handler 461, which is near the FOUPS in the FIG. 4A embodiment, is configured to load substrates onto the aligner 468. From the aligner 468, the substrates are transferred to the vacuum or wet pretreat unit by a transit arm that that module.

In various embodiments, a plasma pretreatment module and a pre-wetting module are provided in close-proximity and in a common vacuum environment, as both modules may operate below atmospheric pressure. In some implementations, the plasma pretreatment module operates at a lower pressure than the pre-wetting module.

Systems having a plasma pretreatment module proximate a prewet module may reduce or eliminate exposure of sensitive seed or liner layers to atmospheric oxygen after pretreatment and before pre-wetting. In certain embodiments, the prewet module is configured as a transfer loadlock for movement of substrates from the plasma unit to the backend of the tool containing electroplating cells. In other words, the plasma pretreatment module operates at high vacuum, the electroplating cell operates at atmospheric pressure, and prewet module operates at an intermediate pressure. In such cases, the tool may be configured such that substrates are transferred directly from the plasma pretreatment module to the prewet module, without breaking vacuum. This configuration may reduce the time it takes for wafer transfers through the tool. In some such embodiments, a separate loadlock is provided between the pretreatment and pre-wetting modules. Regardless of whether the prewet module serves as a loadlock or a separate loadlock is provided between the plasma processing module and the prewet module, the system may have a relatively small footprint compared to systems in which the pretreatment and pre-wetting modules are widely separated.

FIG. 4C presents an example of a single electroplating cell 401 that may be employed to electroplate Co, Ni, and alloys thereof. In certain embodiments, cell 401 may serve as one of cells 453 in platform 451 of FIG. 4A. Additives (e.g., accelerators, suppressors, and/or levelers) added to the electrolyte may react with the anode in undesirable ways. Therefore, anodic and cathodic regions of the electroplating cell are sometimes separated by a membrane so that plating solutions of different composition may be used in each region. Electroplating solution in the cathodic region is called catholyte; and in the anodic region, anolyte. A number of engineering designs can be used in order to introduce anolyte and catholyte into the plating apparatus.

Referring to FIG. 4C, a diagrammatical cross-sectional view of the electroplating apparatus 401 in accordance with one embodiment is shown. An electroplating bath 403 is shown at a level 405. A catholyte portion of this vessel is adapted for receiving substrates in a catholyte. A wafer 407 is immersed into the plating solution and is held by, e.g., a “clamshell” substrate holder 409, mounted on a rotatable spindle 411, which allows rotation of clamshell substrate holder 409 together with the wafer 407. A general description of a clamshell-type plating apparatus having aspects suitable for use with this invention is described in detail in U.S. Pat. No. 6,156,167 issued to Patton et al., and U.S. Pat. No. 6,800,187 issued to Reid et al., which are incorporated herein by reference in their entireties.

An anode 413 is disposed below the wafer within the electroplating bath 403 and is separated from the wafer region by a membrane 415 such as an ion selective membrane. These membranes may be made of ionomeric materials, such as perfluorinated co-polymers containing sulfonic groups (e.g. Nafion™), sulfonated polyimides, and other materials known to those of skill in the art to be suitable for cation exchange. Examples of suitable Nafion™ membranes include N324 and N424 membranes available from Dupont de Nemours Co. The region below the anodic membrane is often referred to as an “anode chamber.” The ion-selective anode membrane 415 allows ionic communication between the anodic and cathodic regions of the plating cell, while preventing the particles generated at the anode from entering the proximity of the wafer and contaminating it. The anode membrane may distribute current flow during the plating process and thereby improving the plating uniformity. Detailed descriptions of suitable anodic membranes are provided in U.S. Pat. Nos. 6,146,798 and 6,569,299 issued to Reid et al., both incorporated herein by reference in their entireties.

During electroplating the ions from the plating solution are reduced on the substrate. The metal ions must diffuse through the diffusion boundary layer and into the TSV hole or other feature. A typical way to assist the diffusion is through convection flow of the electroplating solution provided by the pump 417. Additionally, a vibration agitation or sonic agitation member may be used as well as wafer rotation. For example, a vibration transducer 408 may be attached to the clamshell substrate holder 409.

The electroplating solution is continuously provided to bath 403 by the pump 417. In certain embodiments, the plating solution flows upwards through an anode membrane 415 and a diffuser plate 419 to the center of wafer 407 and then radially outward and across wafer 407. The electroplating solution also may be provided into the anodic region of the bath from the side of the plating bath 403. The electroplating solution then overflows plating bath 403 to an overflow reservoir 421. The electroplating solution is then filtered (not shown) and returned to pump 417 completing the recirculation of the plating solution. In certain configurations of the plating cell, a distinct electrolyte is circulated through the portion of the plating cell in which the anode is contained while mixing with the main plating solution is prevented using sparingly permeable membranes or ion selective membranes.

A reference electrode 431 is located on the outside of the plating bath 403 in a separate chamber 433, which chamber is replenished by overflow from the main plating bath 403. Alternatively, in some embodiments the reference electrode is positioned close to the substrate surface, and the reference electrode chamber is connected via a capillary tube or by another method, to the side of the wafer substrate or directly under the wafer substrate. The reference electrode 431 may be one of a variety of commonly used types such as mercury/mercury sulfate, silver chloride, saturated calomel, or copper metal. A contact sense lead in direct contact with the wafer 407 may be used in some embodiments, in addition to the reference electrode, for potential measurement (not shown). In some embodiments, contact sense leads connect to the wafer periphery and are configured to sense the potential of the metal seed layer at the periphery of the wafer but do not carry any current to the wafer.

A DC power supply 435 can be used to control current flow to the wafer 407. The power supply 435 has a negative output lead 439 electrically connected to wafer 407 through one or more slip rings, brushes and contacts (not shown). The positive output lead 441 of power supply 435 is electrically connected to an anode 413 located in plating bath 403. The power supply 435, the reference electrode 431, and a contact sense lead (not shown) can be connected to a system controller 447, which allows, among other functions, modulation of current and potential provided to the elements of electroplating cell. For example, the controller may allow electroplating in potential-controlled and/or current-controlled regimes. The controller may include program instructions specifying current and voltage levels that need to be applied to various elements of the plating cell, as well as times at which these levels need to be changed. When forward current is applied, the power supply 435 biases the wafer 407 to have a negative potential relative to anode 413. This causes an electrical current to flow from anode 413 to the wafer 407, and an electrochemical reduction reaction occurs on the wafer surface (the cathode), which results in the deposition of the electrically conductive layer (e.g. copper) on the surfaces of the wafer. An inert or active anode 414 may be installed below the wafer 407 within the electroplating bath 403 and separated from the wafer region by the membrane 415.

The apparatus may also include a heater 445 for maintaining the temperature of the electroplating solution at a specific level. The electroplating solution may be used to transfer the heat to the other elements of the plating bath. For example, when a wafer 407 is loaded into the plating bath the heater 445 and the pump 417 may be turned on to circulate the electroplating solution through the electroplating apparatus 401, until the temperature throughout the apparatus becomes substantially uniform. In one embodiment the heater is connected to the system controller 447. The system controller 447 may be connected to a thermocouple to receive feedback of the plating solution temperature within the electroplating apparatus and determine the need for additional heating.

The controller will typically include one or more memory devices and one or more processors. The processor may include a CPU or computer, analog and/or digital input/output connections, stepper motor controller boards, etc. In certain embodiments, the controller controls all activities of the electroplating apparatus. Non-transitory machine-readable media containing instructions for controlling process operations in accordance with the present embodiments may be coupled to the system controller.

In certain embodiments, there will be a user interface associated with controller 447. The user interface may include a display screen, graphical software displays of the apparatus and/or process conditions, and user input devices such as pointing devices, keyboards, touch screens, microphones, etc. The computer program code for controlling electroplating processes can be written in any conventional computer readable programming language: for example, assembly language, C, C++, Pascal, Fortran or others. Compiled object code or script is executed by the processor to perform the tasks identified in the program. One example of a plating apparatus that may be used according to the embodiments herein is the Lam Research Sabre tool. Electrodeposition can be performed in components that form a larger electrodeposition apparatus.

### System Controller

In some implementations, a controller is part of a system such as depicted in FIG. 4A and/or FIG. 4B. For example, a system may comprise semiconductor processing equipment, including a processing tool or tools, chamber or chambers, a platform or platforms for processing, and/or specific processing components (a wafer holder, a electrolyte recirculation system, etc.). As an example, see the discussion of FIG. 4A. These systems may be integrated with electronics and/or logic for controlling their operation before, during, and after processing of a semiconductor wafer or substrate. The electronics and/or logic may be referred to as the “controller,” which may control various components or subparts of the system or systems. The controller, depending on the processing requirements and/or the type of system, may be programmed to control any of the processes disclosed herein, including temperature settings (e.g., heating and/or cooling), pressure settings, electrical current and/or potential settings, flow rate settings, fluid delivery settings, rotational speed settings, substrate immersion settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable electroplating solution composition control, enable electroplating, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. The parameters may be specific to the type of process to be performed and the type of tool that the controller is configured to interface with or control. Thus, as described above, the controller may be distributed, such as by comprising one or more discrete controllers that are networked together and working towards a common purpose, such as the processes and controls described herein. An example of a distributed controller for such purposes would be one or more integrated circuits on an electroplating system in communication with one or more integrated circuits located remotely (such as at the platform level or as part of a remote computer) that combine to control a process on the chamber.

Without limitation, example systems may include a metal electroplating cell or module, a spin-rinse chamber or module, a bevel edge etch chamber or module, a plasma pretreatment module configured to chemically reduce a seed or liner prior to electroplating, a substrate wetting module for wetting features prior to electroplating, etch chamber or module, a deposition chamber or module, a clean chamber or module, a physical vapor deposition (PVD) chamber or module, a chemical vapor deposition (CVD) chamber or module, an atomic layer deposition (ALD) chamber or module, an atomic layer etch (ALE) chamber or module, a photoresist application and/or patterning module, an ion implantation chamber or module, a track chamber or module, and any other semiconductor processing systems that may be associated or used in the fabrication and/or manufacturing of semiconductor wafers.

Depending on the process step or steps to be performed by the tool, the controller might communicate with one or more of other tool circuits or modules, other tool components, cluster tools, other tool interfaces, adjacent tools, neighboring tools, tools located throughout a fabrication facility, a main computer, another controller, or tools used in material transport that bring containers of wafers to and from tool locations and/or load ports in a semiconductor device manufacturing facility.

### Examples

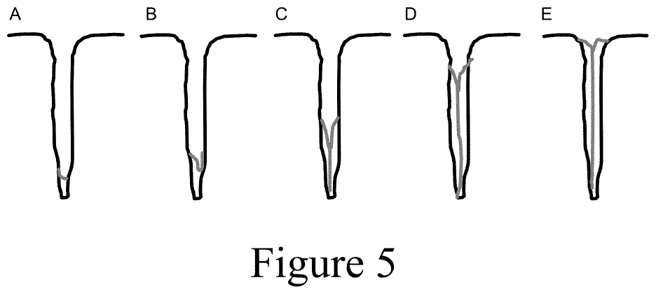

FIGS. 5-8 illustrate data obtained while designing a cobalt electroplating process for TSV features. FIG. 5 provides traces of fill in TSV features (CD 100 nm, Depth 1000 nm). A series of constant current fill steps were used with the same solution formulation to determine current densities to use when beginning to fill the feature and when completing fill of the feature. This data illustrates that a seam void formed. Nevertheless, by performing these types of experiments for different solution formulations a process designer can tune the solution composition and current process window to minimize the seams and voids.

The depicted example shows cobalt fill progression with constant current fill step: (A) 0.2 mA/cm2 1600 s, (B) 0.4 mA/cm2, 800 s, (C) 0.7 mA/cm2, 450 s, (D) 1 mA/cm2, 300 s. This test series shows that fill begins at 0.4 mA/cm2 and ends at 1 mA/cm2. The seam void is represented by the line in the center of the features C-E. All drawings are traces of actual feature fill data.

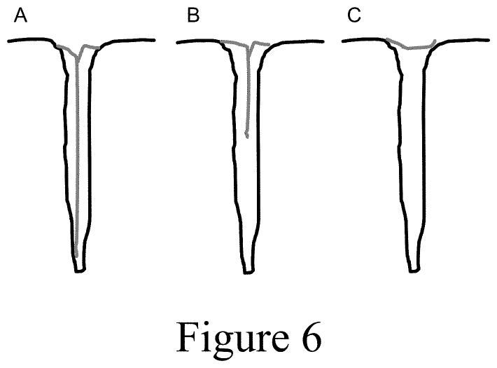

FIG. 6 illustrates another method of process development. It involves additional fine tuning the process window through an iterative process of additive concentration, pH, mass transport and waveform ramping tests. Achieving void free fill in the deep structures requires a balance of enough field passivation to prevent upper sidewall deposition, but not too much passivation into the feature to stop deposition entirely. The waveform is ramped to higher currents to progress the fill front as it moves up the feature and encounters higher suppressor concentrations and higher hydrogen ion concentrations that decrease the metal deposition rate.

In FIG. 6, (A) illustrates an unoptimized waveform or plating condition with a clear seam void, (B) illustrates a condition that has good bottom up fill for a portion of the feature and then a seam void, (C) shows the result of an electrofill process window that produced no voiding. Void free fill is obtained through process variable testing of pH, additive concentration, mass transport (RPM), and waveform ramping. All these drawings are traces of actual feature fill data.

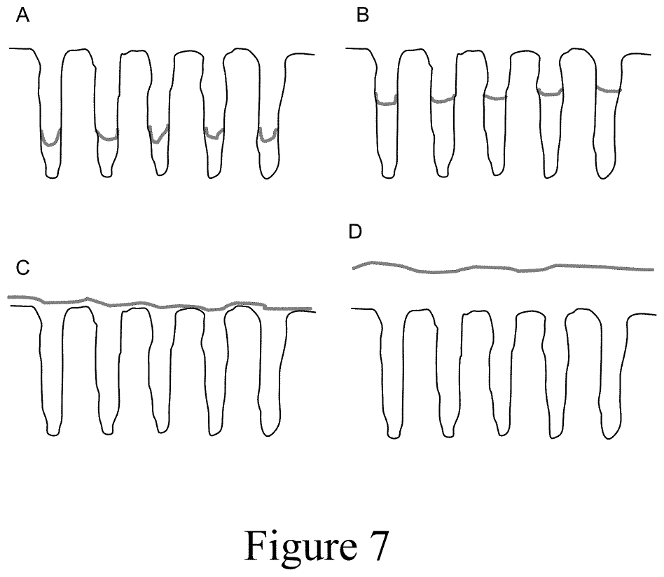

FIG. 7 provides additional traces of electrofill cobalt into high aspect ratio TSV features. It shows a how desired bottom up fill process proceeds. The series of figures show the extension of a ramped waveform to start a flat fill front, progress it up the feature, and complete the feature fill. In FIG. 7, (A) illustrates a ramp from about 0.5>0.7 mA/cm2, 60 s, (B) illustrates the ramp being increased in duration at the same ramp rate (0.5-1 mA/cm2, 120 s), (C) illustrates the completion of void free fill 0.5-1.8 mA/cm2, 350 s, (D) shows additional overburden being plated onto the fully filled features. Overburden may be added through either a ramped current or constant current waveform. All of these drawings are traces of actual feature fill data.

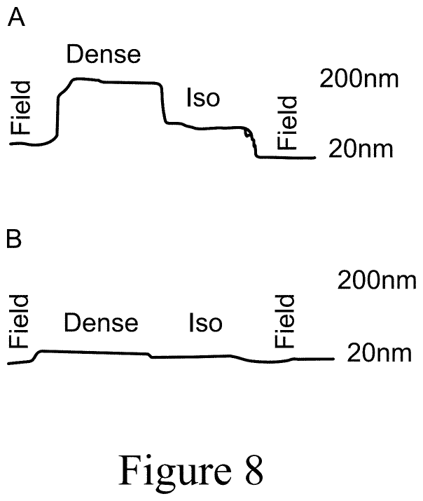

Overburden is deposited (D) by continuing to ramp the current or changing to a higher constant current density. During the overburden deposition significant topography variations can occur over dense, isolated patterns, and regions of unpatterned field due to differences in adsorbed suppressor. An example of the topography improvement observed from adding a leveling compound to an electroplating solution is shown in FIG. 8. In FIG. 8, topography of overburden features is shown in (A) without leveler and (B) with leveler. Data is a height profile taken from an optical profilometer.

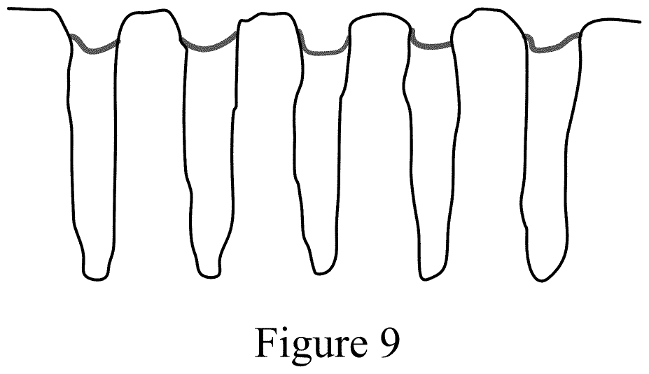

FIG. 9 illustrates an electroplating process design, similar to that illustrated above for cobalt, but for nickel in this case. Nickel is electrodeposited into high aspect ratio TSVs. The solution conditions and current conditions were tuned to obtained void free Ni into the same structures. In this case, the solution had the following composition: Ni: ion 25 g/L; Boric 10 g/L; pH 4.0. In this case, the current ramp had the following profile: 0.5->1.75 mA/cm2 over 350 s. The substrate was rotated at 50 RPM during electroplating.

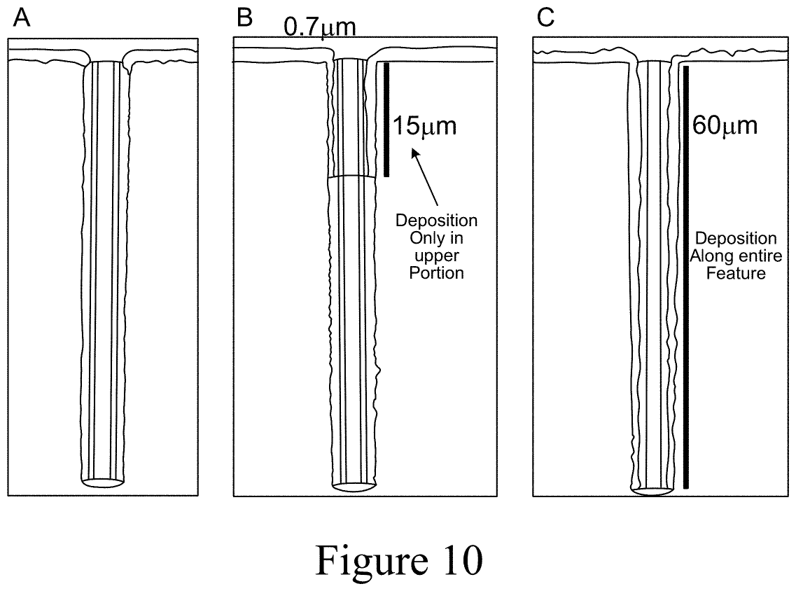

FIG. 10 provides an example of the impact of a vacuum pre-wetting of deep TSV structures. In FIG. 10, panel (A) shows a seed only image, panel (B) shows that electroplating occurs only at top of large TSV (6×60 micrometers) without prewet treatment, and panel (C) shows cobalt plating can be extended all through the TSV by using prewet treatment before deposition.

In panel B metal deposition is only observed onto the field and top sidewall of the structure because the bottom of the feature has trapped air that does not allow the electroplating solution to access the feature and begin electroplating. In panel C, the same electroplating process was run, but before electroplating the sample was placed under a vacuum to evacuate air and then the wafer was coated with a thin layer of water. When the sample was moved over to the electroplating cell it retained the thin layer of adhered water and air is not trapped in the feature. Panel C shows Co electroplating along the sidewall all the way into the via bottom. In various embodiments, vacuum pre-wetting feature is used with certain deep features. The solution used for pre-wetting the wafer may also contain suppressor or a wetting agent to improve air clearance and fill. The solution for pre-wetting might also contain some accelerator or leveler for specific applications.

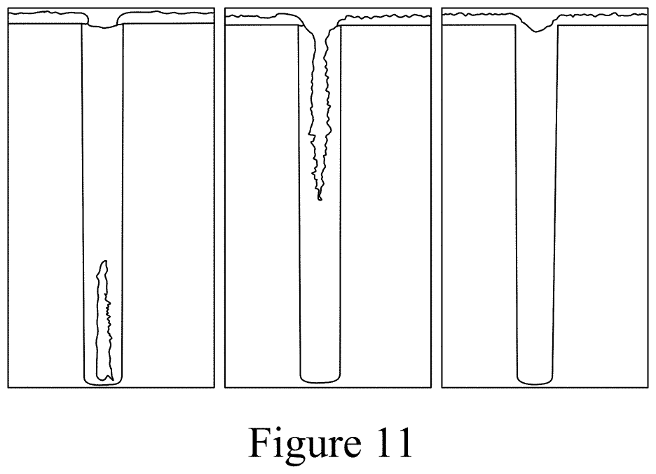

FIG. 11 illustrates process tuning for void free fill in larger TSV structures. If the electroplating rate of Co on the field and upper sidewall are not slowed sufficiently by additive suppression or low current efficiency due to competition with hydrogen reduction (FIG. 1) then the feature will electroplate too rapidly high in the feature. This leads to a bottom void as shown in panel A. The bottom void is removed in this series (panel B) of images by lowering the pH of the solution to supply more H⁺ ion into the system. The additional H⁺ ions are reduced preferentially by the electroplating current in the system and lower the current efficiency for Co²⁺ reduction. Once H⁺ is depleted in the deep TSV, the only ion left is Co²⁺ and it begins to deposit at the bottom of the feature. Further up in the feature mass transport of H⁺ into the via from the bulk solution keeps the H⁺ concentration high and the Co²⁺ reduction rate low. In panel C the waveform is adjusted slightly to progress fill up the feature in the same solution as used in panel B. FIG. 11 illustrates that tuning process similar to that described for smaller TSVs (FIG. 5-9) can be applied to large TSV features.

In FIG. 11, panel (A) illustrates TSV feature filled with Co deposition too fast at top of feature leading to pinch off void. This result indicates a need for as faster deposition rate at the bottom and slower deposition rate at the top. To achieve this the suppressor concentration, pH, mass transport, and plating current may be tuned. In panel (B), the bottom of the TSV feature has been filled through an improved process. To complete the electrofill, the plating may be modulated to avoid a pinch off void at the top of the feature. Panel (C) illustrates a fully filled 6×60 micrometer feature.

### CONCLUSION

Although the foregoing embodiments have been described in some detail for purposes of clarity of understanding, it will be apparent that certain changes and modifications may be practiced within the scope of the appended claims. Embodiments disclosed herein may be practiced without some or all of these specific details. In other instances, well-known process operations have not been described in detail to not unnecessarily obscure the disclosed embodiments. Further, while the disclosed embodiments will be described in conjunction with specific embodiments, it will be understood that the specific embodiments are not intended to limit the disclosed embodiments. It should be noted that there are many alternative ways of implementing the processes, systems, and apparatus of the present embodiments. Accordingly, the present embodiments are to be considered as illustrative and not restrictive, and the embodiments are not to be limited to the details given herein.

1. A method of forming an interconnect in an electronic device, the method comprising:
(a) contacting a substrate comprising a partially or fully fabricated integrated circuit with an aqueous electroplating solution having a pH of about 2 to about 5, and comprising:
(i) nickel ions in a concentration of about 20 to about 80 g/L and/or cobalt ions in a concentration of about 10 to about 40 g/L; and
(ii) a suppressor, wherein the substrate comprises features having a diameter of about 0.005-6 micrometers and a feature depth of about 0.05-10 micrometers; and
(iii) controlling an electrical current and/or voltage to the substrate, thereby electroplating nickel and/or cobalt from the electroplating solution, via a bottom up fill mechanism, into the features.

2. The method of claim 1, wherein the features have a depth of about 1000 nm to about 2000 nm and an opening diameter or width of about 50 nm to about 150 nm.

3. The method of claim 1, wherein the features are micro TSV features.

4. The method of claim 2 wherein electroplating nickel and/or cobalt into the one or more features produces one or more interconnects between first electronic devices on a first side of the substrate to second electronic devices on a second side of the substrate.

5. The method of claim 1, wherein the features have a depth of about 50 nm to about 500 nm and an opening diameter or width of about 5 nm to about 20 nm.

6. The method of claim 1, wherein electroplating nickel and/or cobalt into the one or more features produces one or more electrical contacts directly to a first electronic device on the substrate.

7. The method of claim 6, wherein the one or more electrical contacts contact one or more 3D NAND devices.

8. The method of claim 1, wherein the aqueous electroplating solution comprises no accelerator or leveler.

9. The method of claim 1, wherein the aqueous electroplating solution further comprises an accelerator and/or a leveler.

10. The method of claim 1, wherein the aqueous electroplating solution further comprises boric acid.

11. The method of claim 1, wherein the aqueous electroplating solution further comprises ions of a metal other than cobalt or nickel, and wherein controlling the electrical current and/or voltage to the substrate electroplates a nickel alloy or a cobalt alloy from the electroplating solution into the features

12. The method of claim 11, wherein the metal other than cobalt or nickel is selected from the group consisting of Cu, Ag, Au, Mn, Fe, Cr, Ru, Mo, Ir, Re, Pd, W, Mo, and Pt.

13. The method of claim 11, wherein the metal other than cobalt or nickel is W or Mo.

14. The method of claim 1, wherein the aqueous electroplating solution further comprises ions of Mo and/or ions of W in a concentration of about 0.1 to about 30 g/L.

15. The method of claim 11, wherein the aqueous electroplating solution further comprises a complexing agent that complexes nickel ions, cobalt ions, or the ions of a metal other than cobalt or nickel.

16. The method of claim 1, wherein controlling an electrical current and/or voltage to the substrate comprises increasing the electrical current during a period while electroplating nickel and/or cobalt from the electroplating solution.

17. The method of claim 16, wherein increasing the current comprises ramping the electrical current.

18. The method of claim 1, further comprising, prior to electroplating nickel and/or cobalt, pretreating the substrate with a plasma to reduce metal oxide on a conductive layer in the one or more features.

19. The method of claim 1, further comprising, prior to electroplating nickel and/or cobalt, prewetting the substrate, under reduced pressure, with a wetting solution that wets the features.

20. The method of claim 1, further comprising, after electroplating nickel and/or cobalt, annealing the substrate.

21. The method of claim 1, wherein the suppressor is selected from the group consisting of ethers, esters, glycols, thiazoles, pyridines, polymeric compounds, and any combination thereof.

22. The method of claim 1, wherein the aqueous electroplating solution further comprises a leveler selected from the group consisting of alkylamines, aryl amines, aromatic nitrogen heterocycles, benzothiazoles, cyclic imides, benzoic acids, epoxides, polymeric compounds, and any combination thereof.

23. The method of claim 1, wherein the aqueous electroplating solution further comprises an accelerator selected from the group consisting of sulfonic acid esters, sulfonic acid salts, mercapto compounds, triazole compounds, and any combination thereof.

24. An apparatus for processing a substrate, the apparatus comprising:
(b) a one or more electroplating cells;
(c) one or more post electrofill modules;
(d) a plasma pretreatment module;
(e) a pre-wetting module;
(f) one or more substrate transfer handlers; and
(g) a controller configured to cause the one or more substrate transfer handlers to process first substrates by transferring them to each of modules (b), (c), and (d), and to process second substrates without transferring them to at least one of modules (b), (c), and (d) during the entire period when the second substrates are within the apparatus.

25. The apparatus of claim 24, further comprising a frame or chassis enclosing the one or more electroplating cells, the one or more post electrofill modules, the pre-wetting module, the plasma pretreatment module, and the substrate transfer handlers.

26. The apparatus of claim 24, further comprising an anneal chamber configured to heat the substrate after electroplating in the one or more electroplating cells.

27. The apparatus of claim 24, wherein the pre-wetting module and the plasma pretreatment module are in a common vacuum environment.

28. The apparatus of claim 24, further comprising a load lock and wherein the prewetting module and the pretreatment module are connected by the load lock.

29. The apparatus of claim 24, wherein the controller is further configured to cause the apparatus to
(i) process a first substrate by transferring it to the plasma pretreatment module and the pre-wetting module prior to transferring it to a first one of the one or more electroplating cells; and
(ii) process a second substrate by transferring it to the pre-wetting module, without transferring it to the plasma pretreatment module prior to transferring it to the first one of the one or more electroplating cells.

30. The apparatus of claim 29, wherein the controller is further configured to cause the apparatus to
(iii) process a third substrate by transferring it to the first one of the one or more electroplating cells without previously transferring it to the pre-wetting module or to the plasma pretreatment module.

31. The apparatus of claim 24, further comprising an electrical power supply configured to control electrical current and/or voltage applied to substrates in the one or more electroplating cells.

32. The apparatus of claim 31, wherein the controller is configured to ramp electrical current during electroplating a first one of the one or more electroplating cells.

33. A method of forming an interconnect in an electronic device, the method comprising:
(h) contacting a substrate comprising a partially or fully fabricated integrated circuit with an aqueous electroplating solution having an acidic pH, and comprising:
(i) nickel ions in a concentration of at least about 20 g/L and/or cobalt ions in a concentration of at least about 10 g/L, and
(ii) a suppressor,
a. wherein the substrate comprises recessed features; and
b. controlling an electrical current and/or voltage to the substrate, thereby electroplating nickel and/or cobalt from the electroplating solution, via a bottom up fill mechanism, into the features.

34. The method of claim 33, wherein the features are micro TSV features.

35. The method of claim 33, wherein electroplating nickel and/or cobalt into the one or more features produces one or more electrical contacts directly to a first electronic device on the substrate.

36. The method of claim 35, wherein the one or more electrical contacts contact one or more 3D NAND devices.
